(19) United States
(12) Patent Application Publication
(10) Pub. No.: US 2025/0062175 A1
(43) Pub. Date: Feb. 20, 2025

(54) SUBSTRATE AND METHOD OF PRODUCING A SUBSTRATE

(71) Applicant: Infineon Technologies AG, Neubiberg (DE)

(72) Inventors: Charles Rimbert-Riviere, Soest (DE); Georg Troska, Fröndenberg (DE); Lydia Lottspeich, Warstein (DE); Martin Goldammer, Soest (DE); Ulrich Wilke, Soest (DE); Benedikt Domes, Lippstadt (DE); Lars Böwer, Soest (DE)

(21) Appl. No.: 18/802,475

(22) Filed: Aug. 13, 2024

(30) Foreign Application Priority Data
Aug. 14, 2023 (DE) 102023121708.9

(51) Int. Cl. H01L 23/31; H01L 23/00; H01L 23/29; H01L 25/07

(52) U.S. Cl. CPC H01L 23/3171; H01L 23/296; H01L 24/27; H01L 24/32; H01L 25/072; H01L 2224/2781; H01L 2224/32227; H01L 2924/13055

(57) ABSTRACT

A method for producing a substrate for a semiconductor module includes: forming a first electrically conductive layer on a first side of a dielectric insulation layer; structuring the first electrically conductive layer by creating one or more incisions through the first electrically conductive layer that extend from an upper surface of the first electrically conductive layer down to the dielectric insulation layer, thereby completely separating different sections of the first electrically conductive layer; and forming a passivation layer covering the entire upper surface of the structured first electrically conductive layer.

### RELATED APPLICATIONS

The instant application claims priority to German Patent Office application 102023121708.9 filed on Aug. 14, 2023, the content of said application being incorporated by reference herein in its entirety.

### TECHNICAL FIELD

The present invention relates to a substrate and to a method of producing a substrate, more particularly to a method of producing a substrate for a power semiconductor module.

### BACKGROUND

Power semiconductor modules usually comprise one or more substrates which may be disposed on a baseplate or on a heatsink. A semiconductor arrangement comprising a multitude of controllable semiconductor components (e.g. IGBTs) is disposed on at least one of the substrates. A substrate generally comprises an electrically insulating substrate layer (e.g. a ceramic layer), a first electrically conductive layer (e.g. a metal layer) disposed on a first side of the substrate layer, and a second electrically conductive layer (e.g. a second metal layer) disposed on a second side of the substrate layer that is opposite the first side. The controllable semiconductor components are disposed, for example, atop the first electrically conductive layer. The second electrically conductive layer is usually connected to the baseplate or heatsink; this means that it is disposed between the baseplate/heatsink and the electrically insulating substrate layer.

At least the first electrically conductive layer is generally a structured layer. This means that the layer has multiple sections which are spaced apart from one another and which are separated from one another by incisions through the first electrically conductive layer. The different sections may be produced by appropriate structuring, i.e, etching, of an initially continuous electrically conductive layer. The continuous electrically conductive layer may already have been contaminated prior to structuring. In addition, the structuring may also give rise to contaminants that may remain in an unwanted manner on the first electrically conductive layer after the structuring process. However, any contaminants cannot always reliably be removed completely in specific cleaning steps that usually follow the structuring. If components are then soldered onto the contaminated first electrically conductive layer, it is possible for even individual very small contaminants to cause unwanted damage.

There is therefore a need for a substrate and a method of producing a substrate that has a minimum propensity to be damaged in spite of possible contaminants.

### SUMMARY

A method for producing a substrate for a semiconductor module comprises: forming a first electrically conductive layer on a first side of a dielectric insulation layer, structuring the first electrically conductive layer by creating one or more incisions through the first electrically conductive layer that extend from an upper surface of the first electrically conductive layer down to the dielectric insulation layer, in order thus to completely separate different sections of the first electrically conductive layer, and the forming of a passivation layer, where the passivation layer covers the entire upper surface of the structured first electrically conductive layer.

A substrate for a semiconductor module has a dielectric insulation layer, a first electrically conductive layer disposed on a first side of the dielectric insulation layer, and a passivation layer, where the first electrically conductive layer is a structured layer having one or more incisions between different completely separated sections of the first electrically conductive layer, and the passivation layer covers an entire upper surface of the structured first electrically conductive layer.

The invention will now be more particularly elucidated by means of examples and with reference to the figures. The same reference numerals here denote identical elements. The illustration in the figures is not necessarily to scale.

### BRIEF DESCRIPTION OF THE DRAWINGS

FIG. 1 illustrates by way of example a cross section through a substrate with semiconductor bodies disposed thereon;

FIGS. 2A to 2D illustrate a conventional method of producing a substrate; and

FIGS. 3A and 3B illustrate a schematic of a method of producing a substrate in one example.

### DETAILED DESCRIPTION

In the detailed description that follows, specific examples will be used to illustrate how the invention can be implemented. It will be apparent that the features of the various examples described herein can be combined with one another, unless stated otherwise. Where particular elements are referred to as “first element”, “second element”, . . . or the like, the identifier “first”, “second”, . . . merely serves to distinguish different elements from one another. No order or listing is associated with this identification. This means that, for example, a “second element” may be present even when no “first element” is present.

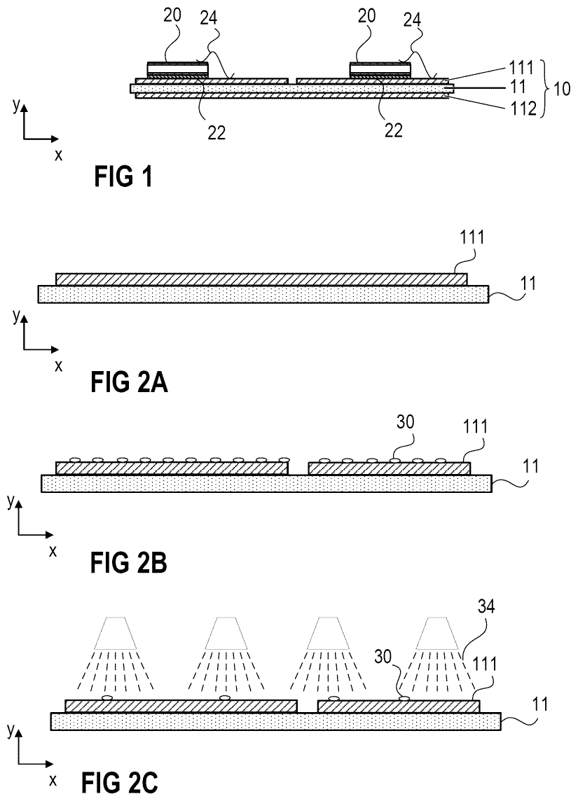

Referring to FIG. 1, a substrate 10 is shown. The substrate 10 comprises a dielectric insulation layer 11, a structured first electrically conductive layer 111 and a (structured) second electrically conductive layer 112. The first electrically conductive layer 111 is disposed on a first side of the dielectric insulation layer 11 and the second electrically conductive layer 112 is disposed on a second side of the dielectric insulation layer 11 that is opposite the first side. The dielectric insulation layer 11 is therefore disposed between the first electrically conductive layer 111 and the second electrically conductive layer 112. However, the second electrically conductive layer 112 is merely optional. It is equally possible to dispose only the first electrically conductive layer 111 atop the dielectric insulation layer 11 and to completely omit the second electrically conductive layer 112.

Each of the first electrically conductive layer 111 and the second electrically conductive layer 112 may consist of one of the following materials or comprise one of the following materials: copper; a copper alloy; aluminum; an aluminum alloy; any other metal or any other metal alloy that remains in a solid state during the operation of the power semiconductor module. The substrate 10 may be a ceramic substrate, i.e., a substrate in which the dielectric insulation layer 11 consists of ceramic. Therefore, the dielectric insulation layer 11 may, for example, be a thin ceramic layer. The ceramic of the dielectric insulation layer 11 may, for example, consist of one of the following materials or comprise one of the following materials: aluminum oxide; aluminum nitride; zirconium oxide; silicon nitride; boron nitride; or any other ceramic. For example, the dielectric insulation layer 11 may consist of one of the following materials or comprise one of the following materials: Al₂O₃, AlN, or Si₃N₄. The substrate 10 may, for example, be what is called a direct copper bonding (DCB) substrate, a direct aluminum bonding (DAB) substrate, an insulated metal substrate (IMS) or an active metal brazing (AMB) substrate. The substrate 10 may, for example, also be a conventional printed circuit board (PCB) having a nonceramic dielectric insulation layer 11. A nonceramic dielectric insulation layer 11 may consist, for example, of a cured resin or comprise a cured resin.

Additionally referring to FIG. 1, one or more semiconductor bodies 20 may be disposed atop the substrate 10. Each of the semiconductor bodies 20 on the substrate 10 may comprise a diode, an IGBT (insulated-gate bipolar transistor), an MOSFET (metal-oxide-semiconductor field-effect transistor), a JFET (junction-gate field-effect transistor), an HEMT (high-electron-mobility transistor), or any other suitable controllable or non-controllable semiconductor component. The one or more semiconductor bodies 20 may form a semiconductor arrangement (for example one or more half-bridges) on the substrate 10. FIG. 1 shows only two semiconductor bodies 20 by way of example.

The first electrically conductive layer 111 shown in FIG. 1 is a structured layer. In this connection, “structured layer” means that the first electrically conductive layer 111 is not a continuous layer; instead, it has interruptions between different sections of the layer. Various semiconductor bodies 20 may be disposed on the same section or on different sections of the first electrically conductive layer 111. Either the different sections of the first electrically conductive layer 111 may have no electrical connection to one another or they may be connected electrically to one another, for example by means of bonding wires. Each of the semiconductor bodies 20 may be electrically and mechanically connected to the substrate 10 by means of an electrically conductive connection layer 22. FIG. 1 shows, by way of example, a substrate 10 having semiconductor bodies 20 and connection layers 22 disposed thereon. Such an electrically conductive connection layer 22 may, for example, be a solder layer. The second electrically conductive layer 112 (if present) may be either a continuous layer or likewise a structured layer.

In order to connect the semiconductor bodies 20 to the substrate 10, the semiconductor bodies 20 are arranged on the surface (top surface) of the substrate 10, with the connection layer 22 disposed between the substrate 10 and the semiconductor body 20. The top surface of the substrate 10 is a surface of the first electrically conductive layer 111 that faces away from the dielectric insulation layer 11. Alternatively or additionally, one or more of the semiconductor bodies 20 may also be connected to the substrate 10 by means of bonding wires 24 for example. The substrate 10 having the at least one semiconductor body 20 disposed thereon may, for example, be part of a power semiconductor module and be disposed in a housing (not shown).

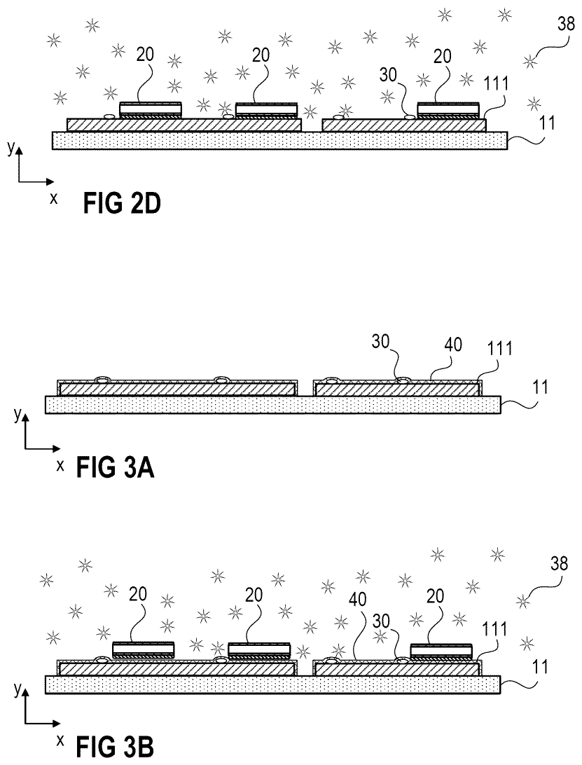

Now referring to FIGS. 2A through 2D, a method of producing a substrate 10 is shown in schematic form. As shown in FIG. 2A, in general, a continuous first electrically conductive layer 111 is first applied (for example by suitable deposition methods) atop the dielectric insulation layer 11. This continuous first electrically conductive layer 111 is structured in a subsequent method step. This is shown by way of example in FIG. 2B. In the structuring of the first electrically conductive layer 111, incisions are created through the first electrically conductive layer 111 that extend from the upper surface of the first electrically conductive layer 111 down to the dielectric insulation layer 11, in order thus to completely separate the different sections of the first electrically conductive layer 111. The incisions may be produced, for example, by appropriate etching methods (e.g. wet etching methods or dry etching methods). After an etching process for structuring of the first electrically conductive layer 111, however, contaminants 30 that have got on to the first electrically conductive layer 111 even before or else during the structuring may remain on the first electrically conductive layer 111, as shown by way of example in FIG. 2B. On etching of the first electrically conductive layer 111, for example, chemicals such as copper chloride (CuCl), sodium hydroxide (NaOH) or sodium carbonate (Na₂CO₃) are used, which can contaminate the surface of the first electrically conductive layer 111 after the etching process.

For removal of such contaminants 30, a subsequent cleaning process is usually conducted, as shown by way of example in FIG. 2C. Such a cleaning process may in principle comprise one or more steps, in each of which one or more of a multitude of chemicals 34 (e.g. sulfuric acid H₂SO₄ or hydrogen peroxide H₂O₂) are sprayed onto the surface of the first electrically conductive layer 111 and removed again in subsequent rinse steps (not shown explicitly). There may lastly follow a drying step. Such cleaning processes can remove at least a majority of the contaminants 30 from the surface of the first electrically conductive layer 111. As shown schematically in FIG. 2C, however, individual contaminants 30 may still remain on the surface even after thorough cleaning processes.

Now referring to FIG. 2D, in a subsequent step, semiconductor components 20 are bonded to the possibly still contaminated surface of the first electrically conductive layer 111. For example, it is possible to solder semiconductor components 20 onto the first electrically conductive layer 111. For this purpose, for example, solder pastes may be used, or else preformed solder compacts or solder moldings (called solder preforms). When solder preforms are used, the soldering operation is usually conducted in a formic acid-containing atmosphere. The formic acid 38 can react with contaminants 30 remaining on the surface of the first electrically conductive layer 111, or in other words the formic acid 38 can “activate” the contaminants 30. Such activation by formic acid 38 is not usually detectable directly during or immediately after the soldering step. Activation is usually identifiable only at significantly later junctures (for example after not less than 12 or not less than 24 hours). It is often the case that activation of contaminants 30 by formic acid 38 leads to distinctly visible discoloration on the surface of the first electrically conductive layer 111. The activation of contaminants 30 by formic acid 38 can also lead to damage to the substrate 10 and hence to malfunctioning of the semiconductor arrangement disposed on the substrate 10.

For that reason, in one example, a passivation layer 40 is applied at least to the first electrically conductive layer 111 prior to the mounting of elements onto the substrate 10. This is shown by way of example in FIG. 3A. The step shown in FIG. 3A can be conducted, for example, after a cleaning step (cf. FIG. 2C) and before the mounting of components onto the substrate (see FIG. 2D). This means that the passivation layer 40 is applied to the structured but still entirely unpopulated first electrically conductive layer 111. Since there are not yet any components disposed atop the first electrically conductive layer 111, the entire upper surface of the first electrically conductive layer 111 is covered by the passivation layer 40. The passivation layer 40 likewise fully covers any contaminants 30 remaining on the surface of the first electrically conductive layer 111. If semiconductor components 20 are then soldered on in a formic acid-containing atmosphere (see FIG. 3B), the passivation layer 40 constitutes a barrier between the formic acid 38 and the contaminants 30, such that the contaminants 30 cannot be activated by the formic acid.

The passivation layer 40 may have a thickness in vertical direction y (at right angles to the upper surface of the substrate 10) of less than 5 μm, or less than 1 μm. For example, the passivation layer 40 may be what is called a monolayer. Monolayers are thin single layers consisting of atoms, molecules or cells. The thickness of a monolayer corresponds to the thickness of a single atom, molecule or cell. The passivation layer 40 may, for example, be a (mono) layer of organic molecules. The organic molecules may have functional groups that serve to attach the organic molecules to the surface of the first electrically conductive layer 111. Functional groups are atomic groups in organic molecules that have a crucial influence on the properties and reaction characteristics thereof. Such a passivation layer 40 composed of organic molecules is fundamentally heat-resistant and is therefore not damaged during a subsequent soldering process. At the same time, such a (thin) passivation layer 40, however, also has no effect on subsequent soldering processes. This means that semiconductor bodies 20 or any other elements may be soldered onto the substrate 10 in just the same way as substrates without a passivation layer 40. The passivation layer 40 has no effect either on the mechanical stability or on the electrical conductivity of the bonds produced.

The passivation layer 40 may be produced, for example, by means of treatment of the substrate 10 by an HFE (hydrofluoroether) cleaning method. Various HFE solutions as solvents for cleaning are known in principle. HFE cleaning methods are often multistage (e.g. two-stage) cleaning methods. For example, the entire substrate 10 can be immersed into a first wash bath in a first step. The first wash bath may contain, for example, detergents for removal of flux residues (for example what is called “Topklean”, with a small proportion of HFE, for example <50% or <25%). In one or more further steps, the substrate 10 may be immersed into further solutions for the HFE cleaning method, which may have, for example, a predominant proportion (e.g. >50%, or >70%) of HFE. During such a multistage HFE cleaning method, there may be deposition, for example, (during one or more of the individual cleaning steps) of a thin phosphate-containing layer atop the first electrically conductive layer 111, which forms the passivation layer 40. However, treatment by means of an HFE cleaning method for deposition of a passivation layer 40 of phosphate is just one example. Functional groups of organic molecules suitable for formation of a passivation layer 40 may include, for example, one or more of the following: phosphates, thiols, silicones, carbonic acid, esters and nitrides. Different functional groups may be applied simultaneously in one and the same step, or successively in different steps, to the surface of the first electrically conductive layer 111.

The passivation layer 40 may, as described above, be produced, for example, by the dipping of the substrate 10 into a corresponding solution (dip-coating method). However, this is merely an example. The passivation layer 40 may alternatively also be produced by spraying (spray coating method), by plasma-assisted deposition methods (plasma enhanced deposition methods) or by vapor deposition methods.

A substrate 10 for a semiconductor module is shown by way of example in FIG. 3A. The substrate 10 has a dielectric insulation layer 11, a first electrically conductive layer 111 disposed on a first side of the dielectric insulation layer 11, and a passivation layer 40, where the first electrically conductive layer 111 is a structured layer having one or more incisions between different completely separated sections of the first electrically conductive layer 111, and the passivation layer 40 covers the entire upper surface of the structured first electrically conductive layer 111.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for producing a substrate for a semiconductor module, the method comprising:
forming a first electrically conductive layer on a first side of a dielectric insulation layer;
structuring the first electrically conductive layer by creating one or more incisions through the first electrically conductive layer that extend from an upper surface of the first electrically conductive layer down to the dielectric insulation layer, thereby completely separating different sections of the first electrically conductive layer; and
forming a passivation layer covering the entire upper surface of the structured first electrically conductive layer.

2. The method of claim 1, wherein forming the passivation layer comprises:
applying material by a spray coating method; or
applying material by a dip coating method; or
applying material by a plasma coating method; or
applying material by a vapor deposition method.

3. The method of claim 1, wherein the passivation layer has a thickness of less than 5 μm or less than 1 μm.

4. The method of claim 1, wherein the passivation layer is a monolayer.

5. The method of claim 1, wherein the passivation layer comprises organic molecules having at least one functional group.

6. The method of claim 5, wherein the at least one functional group comprises one or more of phosphates, thiols, silicones, carbonic acid, esters, and nitrides.

7. The method of claim 1, wherein forming the passivation layer comprises treating the first electrically conductive layer by a hydrofluoroether (HFE) cleaning method.

8. The method of claim 1, wherein structuring the first electrically conductive layer comprises etching of the one or more incisions by a wet etching method or a dry etching method.

9. The method of claim 1, further comprising:
after the structuring of the first electrically conductive layer and before the forming of the passivation layer, performing at least one cleaning step that removes contaminants from the first electrically conductive layer.

10. The method of claim 9, wherein the passivation layer is applied to the electrically conductive layer in such a way that the passivation layer fully covers contaminants still remaining on the upper surface of the first electrically conductive layer after the at least one cleaning step.

11. The method of claim 1, further comprising:
after the forming of the passivation layer, mounting one or more semiconductor components atop the first electrically conductive layer and the passivation layer by a soldering process.

12. The method of claim 11, wherein the soldering process is conducted using solder preforms and in a formic acid-containing atmosphere.

13. A substrate for a semiconductor module, the substrate comprising:
a dielectric insulation layer;
a first electrically conductive layer disposed on a first side of the dielectric insulation layer, wherein the first electrically conductive layer is a structured layer having one or more incisions between different completely separated sections of the first electrically conductive layer; and
a passivation layer covering an entire upper surface of the structured first electrically conductive layer.
